(19) United States
(12) Patent Application Publication
(10) Pub. No.: US 2012/0037228 A1
(43) Pub. Date: Feb. 16, 2012

(54) Thin-Film Photovoltaic Cell Having Distributed Bragg Reflector

(75) Inventor: Chen-Pang FU, Taipei County (TW)

(73) Assignee: Du Pont Apollo Limited, Hong Kong (HK)

(21) Appl. No.: 13/186,464

(22) Filed: Jul. 19, 2011

Related U.S. Application Data
(60) Provisional application No. 61/372,101, filed on Aug. 10, 2010.

(51) Int. Cl. H01L 31/0232; B82Y 99/00

(52) U.S. Cl. 136/259; 977/773; 977/948

(57) ABSTRACT

A novel back reflector formed by disposing conductive nanostructures in a distributed Bragg reflector for photovoltaic cells is provided. The distributed Bragg reflector is formed by alternatively stacking first refractive layers and second refractive layers. The conductive nanostructures are disposed in the interfaces between the first and the second refractive layers.

### RELATED APPLICATIONS

This application claims priority to U.S. Provisional Application Ser. No. 61/372,101, filed Aug. 10, 2010, which is herein incorporated by reference.

### BACKGROUND

1. Technical Field

The disclosure relates to a thin-film photovoltaic cell. More particularly, the disclosure relates to a thin-film photovoltaic cell having a back reflector.

2. Description of Related Art

Photovoltaic cells, commonly known as solar cells, are well known devices that convert light energy into electricity. Therefore, how to increase the photoelectric conversion efficiency is always an important issue in photovoltaic system. One way is to place a back reflector beneath photoactive semiconductor layers to reflect light unabsorbed by the semiconductor layers to back through the semiconductor layers for further absorption. Accordingly, the use of a back reflector can increase the cell efficiency of the photovoltaic cells.

### SUMMARY

Accordingly, a novel back reflector is provided for photovoltaic cells. This novel back reflector is a distributed Bragg reflector (DBR) containing conductive nanostructures therein. Therefore, the resistivity of the novel DBR can be largely reduced, and the novel DBR can also serve as a metal back contact at the same time. The conductive nanostructures above can be metal nanoparticles or metal thin films distributed in the multi-layered DBR structure.

It is to be understood that both the foregoing general description and the following detailed description are by examples, and are intended to provide further explanation of the invention as claimed.

### BRIEF DESCRIPTION OF THE DRAWINGS

FIG. 1 is a cross-sectional diagram of a conventional photovoltaic cell.

FIG. 2 is a cross-sectional diagram of a photovoltaic cell according to one embodiment of this invention.

FIGS. 3A-4B are cross-sectional diagrams of distributed Bragg reflectors for photovoltaic cells according to embodiments of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

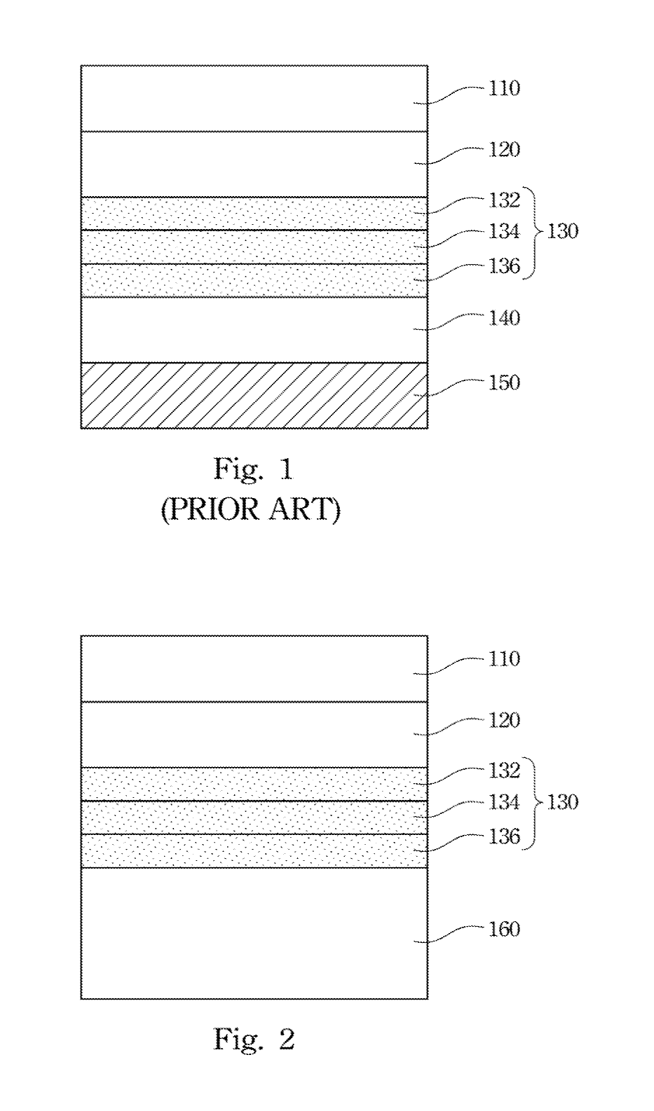

FIG. 1 is a cross-sectional diagram of a conventional photovoltaic cell. In FIG. 1, a conventional photovoltaic cell includes the following layers of a glass substrate 110, a first transparent conductive oxide (TCO) layer 120, a semiconductor layer 130, a second transparent conductive oxide layer 140, and a metal back contact 150. The semiconductor layer 130 usually includes an p-doped semiconductor layer 132, an intrinsic semiconductor layer 134, and a n-doped semiconductor layer 136. The semiconductor layer 130 can be amorphous silicon layer. The first transparent conductive oxide layer 120 can be a tin dioxide layer. The second transparent conductive oxide layer 140 can be an aluminum doped zinc oxide (AZO) layer or a gallium doped zinc oxide (GZO) layer.

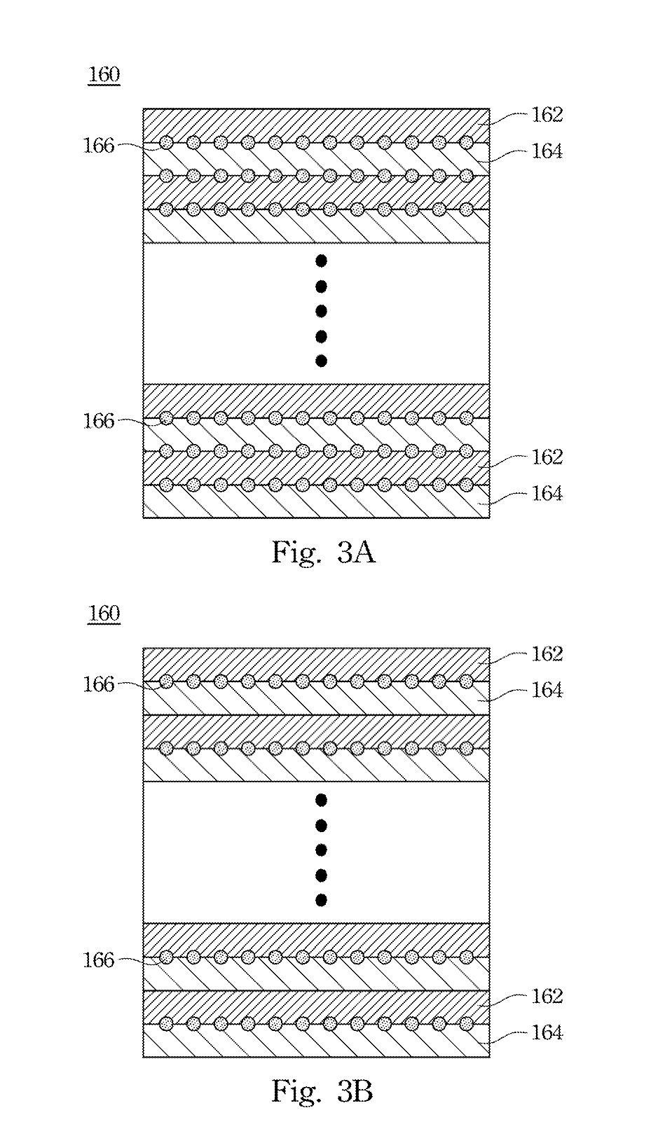

FIG. 2 is a cross-sectional diagram of a photovoltaic cell according to an embodiment of this invention. In FIG. 2, the second transparent conductive oxide layer 140 and a metal back contact 150 are replaced by a novel distributed Bragg reflector 160, which serves as a back reflector and a metal back contact for photovoltaic cells.

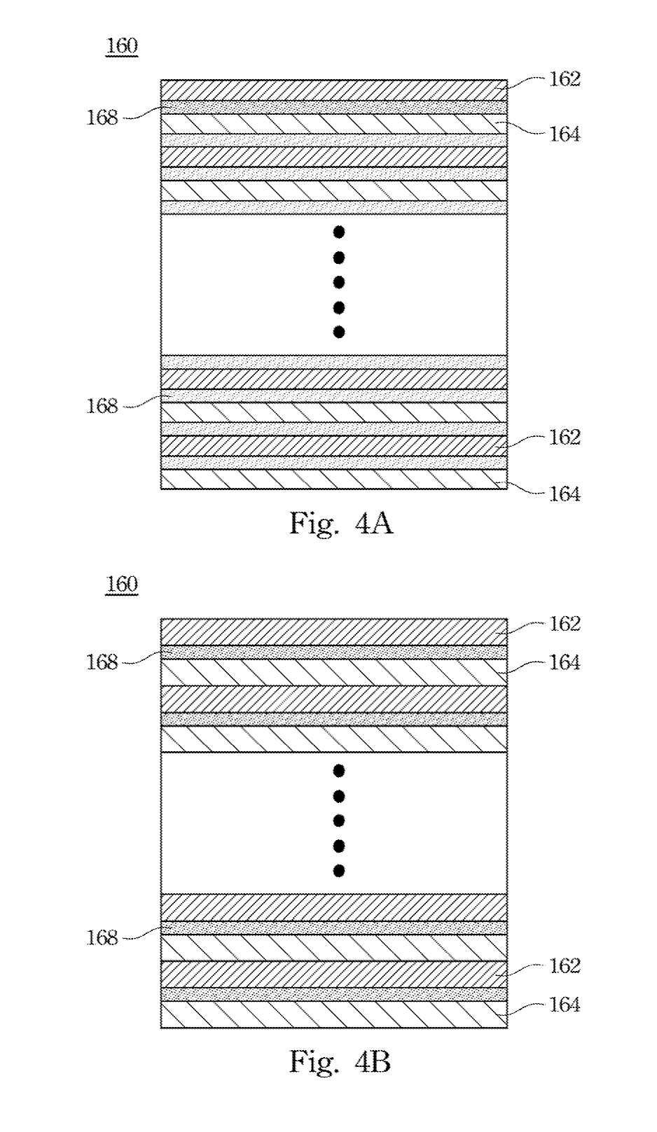

FIGS. 3A-4B are cross-sectional diagrams of distributed Bragg reflectors for photovoltaic cells according to embodiments of this invention. In FIGS. 3A-4B, the distributed Bragg reflector 160 comprises multiple first refractive layers 162 and multiple second refractive layers 164, which are alternatively stacked. The refractive index of the first refractive layers 162 is higher than that of the second refractive layers 164. Please refer to both FIGS. 2 and 3A, the semiconductor layer 130 contacts the upmost first refractive layer 162. Generally, the reflectance (R) of a distributed Bragg reflector can be determined by the following simplified formula.

$$R = 1 = 4 \frac{{n}_{air}}{{n}_{s}} {( \frac{{n}_{L}}{{n}_{H}} )}^{2 N}$$

R: reflectance
n_{L}: lower refractive index
n_{H}: higher refractive index
nₐᵢᵣ: air's refractive index
nₛ: substrate's refractive index
N: pair number of the first and the second refractive layers

Accordingly, the reflectance of the distributed Bragg reflector can be increased by increasing the refractive index difference between the first refractive layers 162 and the second refractive layers 164 and the pair number of the first refractive layers 162 and the second refractive layers 164. Therefore, the reflectance of the distributed Bragg reflector can be adjusted by choosing proper materials for the first refractive layers 162 and the second refractive layers 164. In addition, the required wavelength range to be reflected is dependent on the material and the thickness of the semiconductor layer 130. Generally, for single junction photovoltaic cells, the required wavelength to be reflected is about 500-800 nm. For multiple junction photovoltaic cells, the required wavelength to be reflected is about 800-1200 nm.

Possible choices for the first refractive layers 162 and the second refractive layers 164 can be silicon-based materials, III-V semiconductor materials, or II-VI semiconductor materials, for example. The silicon-based materials can be amorphous silicon, SiGe, amorphous SiGe, amorphous silicon carbide, or silicon oxide, for example. The III-V semiconductor materials can be GaN, GaP, InN, InP, GaAs, InAs, AIN, AlP, or AlAs, for example. The II-VI semiconductor materials can be ZnO, ZnTe, ZnSe, CdTe, CdSe, HgTe, ZnS, CdS, or HgS, for example.

Moreover, the distributed Bragg reflector comprises conductive nanostructures distributed in the interfaces between the first refractive layers 162 and the second refractive layers 164. The material of the conductive nanostructures can be Ag, Al, Pt, In, or Au, for example.

In FIGS. 3A and 3B, the conductive nanostructures can be metal nanoparticles 166, for example. The average diameter of the metal nanoparticels 166 is about 1-2000 Å, preferably 1-1000 Å, and more to preferably 1-200 Å. The average height of the metal nanoparticels 166 is about 1-1000 Å, preferably 1-100 Å, and more preferably 1-50 Å. The difference between FIGS. 3A and 3B is the distribution density of the metal nanoparticels 166. The distribution density of the metal nanoparticels 166 can be used to adjust the resistance of the distributed Bragg reflector according to various needs. For example, in FIG. 3A, the metal nanoparticels 166 are disposed in each interface between the first refractive layers 162 and the second refractive layers 164. In FIG. 3B, the metal nanoparticels 166 are disposed in only each two interfaces between the first refractive layers 162 and the second refractive layers 164.

In FIGS. 4A and 4B, the conductive nanostructures can be metal thin film 168, for example. The thickness of the metal thin film 168 is about 1-200 Å, preferably 1-100 Å, and more preferably 1-50 Å. The difference between FIGS. 4A and 4B is the distribution density of the metal thin film 168. Similarly, the distribution density of the metal thin film 168 can be used to adjust the resistance of the distributed Bragg reflector according to various needs. For example, in FIG. 4A, the metal thin film 168 disposed in each interface between the first refractive layers 162 and the second refractive layers 164. In FIG. 4B, the metal thin film 168 is disposed in only each two interfaces between the first refractive layers 162 and the second refractive layers 164.

Next, the resistances of the distributed Bragg reflectors in FIG. 4A with various thicknesses were measured. When the metal thin film 168 was a silver thin film, the obtained thickness and the resistance are listed in the table below. It can be seen from the table that the resistance can be largely decreased by several orders.

| Thickness (nm) | Resistance (Ohm-cm) |
|---|---|
| 0 | 1 |
| 4 | 0.0025 |
| 6 | 0.0008 |
| 8 | 0.0006 |
| 10 | 0.00055 |

Accordingly, since the distributed Bragg reflector above contains conductive nanostructures distributed therein, the novel distributed Bragg reflector provided above can be used as a back reflector and a back metal contact at the same time.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A thin-film photovoltaic cell having a distributed Bragg reflector, wherein the distributed Bragg reflector comprising:
a plurality of first refractive layers;
a plurality of second refractive layers, wherein the first refractive layers and the second refractive layers are stacked alternatively, wherein the refractive index of the first, refractive layers is higher than the refractive index of the second refractive layers; and
conductive nanostructures distributed in the interface between the first and the second refractive layers.

2. The thin-film photovoltaic cell of claim 1, wherein the conductive nanostructures are made of Ag, Al, Pt, In, or Au.

3. The thin-film photovoltaic cell of claim 1, wherein the conductive nanostructures comprises metal nanoparticles.

4. The thin-film photovoltaic cell of claim 3, wherein the average diameter of the metal nanoparticles is about 1-2000 Å.

5. The thin-film photovoltaic cell of claim 3, wherein the average height of the metal nanoparticles is about 1-1000 Å.

6. The thin-film photovoltaic cell of claim 1, wherein the conductive nanostructures comprises metal thin films.

7. The thin-film photovoltaic cell of claim 6, wherein the thickness of the metal thin films is about 1-200 Å.

8. The thin-film photovoltaic cell of claim 1, wherein the conductive nanostructures disposed in every interface between the first and the second refractive layers.

9. The thin-film photovoltaic cell of claim 1, wherein the conductive nanostructures disposed in a portion of the interfaces between the first and the second refractive layers.

10. The thin-film photovoltaic cell of claim 1, further comprising:
a transparent substrate;
a transparent conductive oxide layer on the transparent substrate; and
a semiconductor layer between the transparent conductive oxide layer and the distributed Bragg reflector, wherein the semiconductor layer contacts one of the first refractive layer.

11. The thin-film photovoltaic cell of claim 1, wherein the material of the first refractive layers and the second refractive layers is silicon-based materials, III-V semiconductor materials, or II-VI semiconductor materials.

12. The thin-film photovoltaic cell of claim 11, wherein the silicon-based materials are amorphous silicon, SiGe, amorphous SiGe, amorphous silicon carbide, or silicon oxide.

13. The thin-film photovoltaic cell of claim 11, wherein the III-V semiconductor materials are GaN, GaP, InN, InP, GaAs, InAs, AlN, or AlP.

14. The thin-film photovoltaic cell of claim 11, wherein the II-VI semiconductor materials are ZnO, ZnTe, ZnSe, CdTe, CdSe, HgTe, ZnS, CdS, or HgS.
